(19) United States
(12) Patent Application Publication
(10) Pub. No.: US 2006/0153404 A1
(43) Pub. Date: Jul. 13, 2006

(54) Parametric equalizer method and system

(76) Inventor: William G. Gardner, Medford, MA (US)

Correspondence Address: Iandiorio & Teska, 260 Bear Hill Road, Waltham, MA, 02451-1018, US

(21) Appl. No.: 11/280,992

(22) Filed: Nov. 17, 2005

Related U.S. Application Data
(60) Provisional application No. 60/641,985, filed on Jan. 7, 2005.

(51) Int. Cl. H03G 5/00

(52) U.S. Cl. 381/103; 381/98

(57) ABSTRACT

Parametric equalization is accomplished by determining an error point for a section of an equalizer frequency response and applying a plurality of different parametric frequency responses to determine the best fit for that error point.

### RELATED APPLICATIONS

This application claims the benefit of U.S. Provision Application No. 60/641,985, filed Jan. 7, 2005, incorporated by reference herein.

### FIELD OF THE INVENTION

This invention relates to a parametric equalizer system and method and more particularly to such a system and method applicable to audio systems such as stereo and 5.1 and 7.1 surround sound systems.

### BACKGROUND OF THE INVENTION

Equalizer filters are widely used to tailor frequency response to a particular desired profile. For example, in the audio field equalizer filters can be used to tailor the frequency response of loudspeakers and rooms. The basic idea is to use a digital processor such as a digital signal processor (DSP) to improve the sound quality of a stereo or 5.1 or 7.1 surround sound system. Most equalization systems have two distinct operational modes: a calibration mode where the response of the system is measured using a microphone and the compensating equalization parameters are determined, and an equalization mode where the equalization is applied to sound playback. Calibration of the system need only be done once after the system is installed but can be repeated after the system is reconfigured.

During the calibration mode an equalization filter is created to be used thereafter to process all signals before they are delivered to the speakers. The filters used to implement the equalization fall into several categories. The earliest approaches used long finite impulse response (FIR) filters, an optimization of this technique uses multi-band filtering and decimation to reduce the computational cost. One problem with all the long FIR approaches is that they seek to de-reverberate the room reverberation, that is, to compensate for the fine details in the room response. The resulting equalization filter works correctly only at the precise measurement location; at other locations the equalized sound is more distorted than the original. Infinite impulse response (IIR) filters have also been used to do speaker/room equalization. They are more efficient than FIR filters, but are more complicated to design.

FIR filter operation requires substantial computational capability which requires powerful DSP's not ordinarily available in sound systems where the existing DSP's are generally meant for simple tasks such as digital decoding for surround sound systems. In contrast IIR filters are well within the capability of such DSP's but the task of determining coefficients for the IIR filter is quite difficult. One technique uses warped filter design which is computationally complex and exceeds the comfortable capability of the existing DSP's in such systems. Warped filter designs also suffer from the shortcoming that they are numerically unstable and become increasingly so with increase in the number of bands processed. The number of bands refers to the number of biquadratic (biquad) equalizer sections. Another problem with these prior art systems is that they are not easily scaleable when, for example, the sampling rate changes from 96 KHz for a DVD to 44 KHz for CD's.

### SUMMARY OF THE INVENTION

It is therefore an object of this invention to provide an improved parametric equalizer method and system.

It is a further object of this invention to provide such an improved parametric equalizer method and system whose design in calibration mode and operation in equalizer mode is achievable on existing sound system DSP's.

It is a further object of this invention to provide such an improved parametric equalizer method and system which does not involve complex computational operations and does not require great numerical precision.

It is a further object of this invention to provide such an improved parametric equalizer method and system which in sound systems more easily produces a large “sweet” spot or listening area.

It is a further object of this invention to provide such an improved parametric equalizer method and system which is scalable to different sampling rates and large numbers of bands or sections.

The invention results from the realization that a parametric equalizer system and method implementable on existing system DSP's and without the usual complex computational operations can be achieved by determining an error point for a section in an equalizer frequency response, determining a characteristic frequency and gain of the error point and applying a plurality of different parametric frequency responses to determine the best fit for that error point.

The subject invention, however, in other embodiments, need not achieve all these objectives and the claims hereof should not be limited to structures or methods capable of achieving these objectives.

This invention features a parametric equalizer method including determining an error point for a section of an equalizer frequency response and applying a plurality of different parametric frequency responses to determine the best fit for that error point.

In a preferred embodiment applying a plurality of different parametric frequency responses may include determining a characteristic frequency and a gain of the error point, and generating a plurality of filter coefficients and corresponding parametric frequency responses of different widths. Applying a plurality of different parametric frequency responses may include comparing each different width parametric frequency response to the equalizer frequency response at a number of frequencies to determine mismatch error. Applying a plurality of different parametric frequency responses may include calculating the sum of the squares of the mismatch errors and selecting the best match. Applying a plurality of different parametric frequency responses may include storing the characteristic frequency and gain of the error point and best match width parametric frequency response. The equalizer frequency response may be normalized using the best match parametric frequency response width to null the error point of the section. The method may further include determining the second error point for a second section applying a plurality of different parametric frequency responses to determine the best fit for that second error point. The method may also include applying, after the best fit has been determined for the last error point section, each of the filter coefficients from each error point section to a filter element to implement an equalizer filter. The method may further include applying the equalizer filter to input signals. The filter elements may be embodied in a digital processor. The characteristic frequency and gain may be the frequency at the peak gain. The equalizer frequency response may be determined by a target frequency response normalized by a measured frequency response.

The invention also features a parametric equalizer including a digital processor configured to determine an error point for a section of an equalizer frequency response and applying a plurality of different parametric frequency responses to determine the best fit for that error point.

In a preferred embodiment the digital processor may be further configured to determine a characteristic frequency and gain of the error point, and generate a plurality of filter coefficients and corresponding parametric frequency responses of different widths. The digital processor may be further configured to compare each different width parametric frequency response to the equalizer frequency response at a number of frequencies to determine mismatch error. The digital processor may be further configured to calculate the sum of the squares of the mismatch errors and select the best match. The digital processor may be configured to store the characteristic frequency and gain of the error point and best match width parametric frequency response. The digital processor may be further configured to normalize the equalizer frequency response using the best match parametric frequency response width to null the error point of the section. The digital processor may be further configured to determine a second error point for a second section and apply a plurality of different parametric frequency responses to determine the best fit for that second error point. The digital processor may be further configured to, after the best fit has been determined for the last error point section, apply each of the filter coefficients from each error point section to a filter element to implement an equalizer filter. The digital processor may be further configured to apply to equalizer filter to input signals. The filter elements may be embodied in the digital processor. The characteristic frequency and gain may be the frequency at the peak gain. The equalizer frequency response may be determined by a target frequency response normalized by a measured frequency response.

This invention also features a method of equalizing a sound system including determining an error point for a section of an equalizer frequency response and applying a plurality of different parametric frequency responses to determine the best fit for that error point.

In a preferred embodiment applying a plurality of different parametric frequency responses may include determining a characteristic frequency and a gain of the error point, and generating a plurality of filter coefficients and corresponding parametric frequency responses of different widths. Applying a plurality of different parametric frequency responses may include comparing each different width parametric frequency response to the equalizer frequency response at a number of frequencies to determine mismatch error. Applying a plurality of different parametric frequency responses may include calculating the sum of the squares of the mismatch errors and selecting the best match. Applying a plurality of different parametric frequency responses may include storing the characteristic frequency and gain of the error point and best match width parametric frequency response. The equalizer frequency response may be normalized using the best match parametric frequency response width to null the error point of the section. The method may further include determining the second error point for a second section applying a plurality of different parametric frequency responses to determine the best fit for that second error point. The method may also include applying, after the best fit has been determined for the last error point section, each of the filter coefficients from each error point section to a filter element to implement an equalizer filter. The method may further include applying the equalizer filter to input signals. The filter elements may be embodied in a digital processor. The characteristic frequency and gain may be the frequency at the peak gain. The equalizer frequency response may be determined by a target frequency response normalized by a measured frequency response.

The invention also features a parametric equalizer for a sound system including a digital processor configured to determine an error point for a section of an equalizer frequency response and apply a plurality of different parametric frequency responses to determine the best fit for that error point.

In a preferred embodiment the digital processor may be further configured to determine a characteristic frequency and gain of the error point, and generate a plurality of filter coefficients and corresponding parametric frequency responses of different widths. The digital processor may be further configured to compare each different width parametric frequency response to the equalizer frequency response at a number of frequencies to determine mismatch error. The digital processor may be further configured to calculate the sum of the squares of the mismatch errors and select the best match. The digital processor may be configured to store the characteristic frequency and gain of the error point and best match width parametric frequency response. The digital processor may be further configured to normalize the equalizer frequency response using the best match parametric frequency response width to null the error point of the section. The digital processor may be further configured to determine a second error point for a second section and apply a plurality of different parametric frequency responses to determine the best fit for that second error point. The digital processor may be further configured to, after the best fit has been determined for the last error point section, apply each of the filter coefficients from each error point section to a filter element to implement an equalizer filter. The digital processor may be further configured to apply the equalizer filter to input s. The filter elements may be embodied in the digital processor. The characteristic frequency and gain may be the frequency at the peak gain. The equalizer frequency response may be determined by a target frequency response normalized by a measured frequency response.

### DESCRIPTION OF THE DRAWINGS

Other objects, features and advantages will occur to those skilled in the art from the following description of a preferred embodiment and the accompanying drawings, in which:

FIG. 1 is a diagrammatic plan view of a room containing a sound system to be calibrated according to the parametric equalizer method and system of this invention;

FIG. 2 is a more detailed schematic diagram of a sound system including this invention;

FIG. 3 is a flow diagram of the parametric equalizer method of this invention;

FIG. 4 is a graphical illustration of target, measured and equalizer frequency responses occurring in the application of the invention in a sound system;

FIG. 5 is a graphical illustration similar to FIG. 4 depicting the attempted fitting of a number of parametric frequency responses of different width to an error point of a first section of the measured frequency response;

FIG. 6 is a graphical illustration similar to FIG. 5 depicting the best match width parametric frequency response to the measured frequency response to normalize the error point of the first section;

FIG. 7 is a graphical illustration similar to FIG. 6 depicting the measured frequency response after normalization of the error point of first section and ready for selection of the next error point in the next section;

FIG. 8 is a more detailed schematic block diagram of a digital signal processor as shown in FIG. 2;

FIG. 9 is a schematic block diagram showing biquad filter elements in the processor of FIGS. 2 and 8;

FIG. 10 is a more detailed schematic diagram of a biquad element of FIG. 9; and

FIG. 11 is a schematic functional block diagram of the digital sign processor data structure and ALU for implementing an embodiment of this invention.

### DISCLOSURE OF THE PREFERRED EMBODIMENT

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

The parametric equalizer method and system of this invention may be used to implement filters in a number of different applications. However, the invention was first applied in a sound system and that will be the embodiment disclosed here, but the invention is not limited to sound systems.

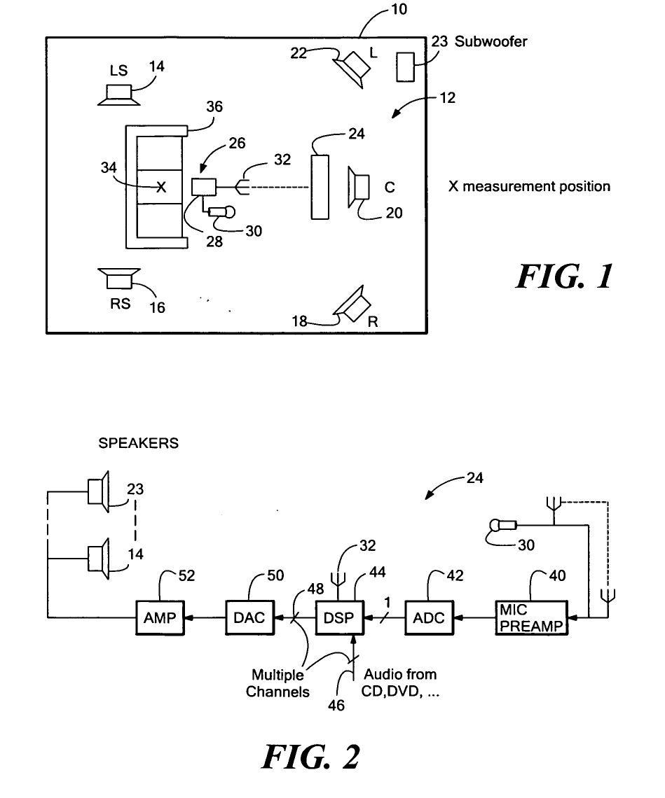

There is shown in FIG. 1 a room 10 including a sound system having five surround sound speakers 14, 16, 18, 20, and 22, a subwoofer speaker 23, an audio processor 24 and a remote control 26 which includes a handset 28, microphone 30, and antenna 32. In operation the user stations himself at point 34 on a couch 36, for example, in front of the forward speakers, 18, 20, and 22. By manipulating control 28 a signal is sent via antenna 32 or by a direct line to the audio processor 24. It then delivers an MLS signal or a pseudo random noise signal or a white noise signal or a chirp signal from a signal generator to each of the speakers 14-23 one at a time. The output of each speaker in sequence is picked up by microphone 30 and through control 28 is delivered to the audio processor 24. Audio processor 24, FIG. 2, includes among other things a microphone pre-amp 40 whose output is delivered to an analog to digital converter 42, the analog output of which is processed by a digital processor such as a digital signal processor 44. Digital signal processor 44 is an essential part of audio processor 24: it receives the audio input from various sources such as CDs and DVDs and includes multiple channels 46 in and 48 out. The output channels 48 are connected to digital to analog converter 50 whose output is amplified by amplifier 52 and delivered to the speakers 14-23.

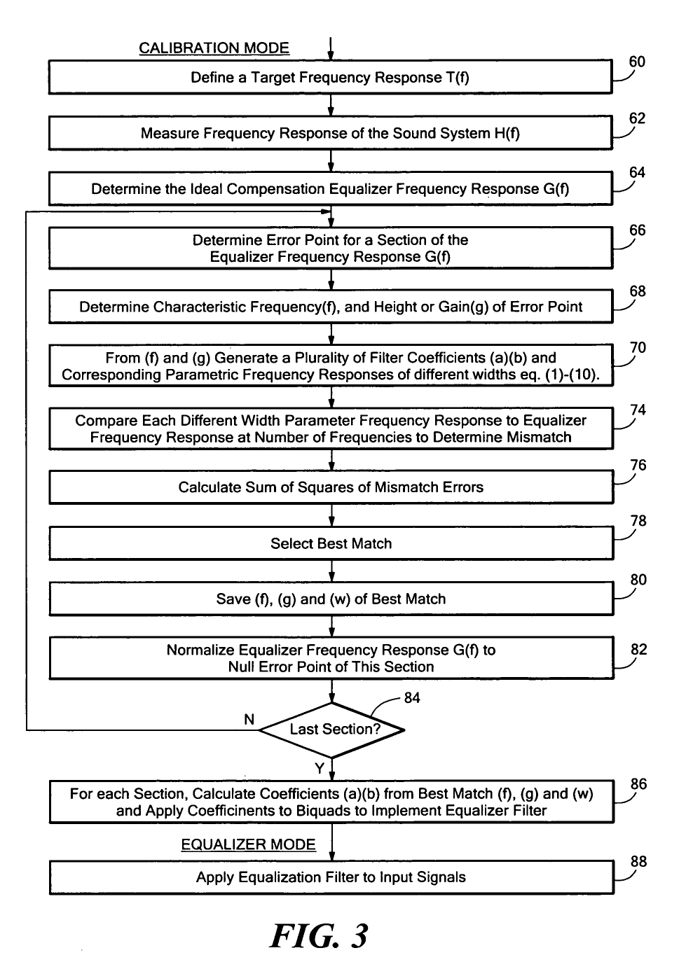

In operation in the calibration mode, FIG. 3, there is first defined a target frequency response T(f), 60, for example, an ISO studio standard. Then the measured frequency response of the sound system H(f) is found, 62, as described in FIG. 1. Continuing in FIG. 3, the ideal compensation equalizer frequency response G(f), 64, is now calculated by normalizing the target frequency response T(f) with the measured frequency response H(f). If in the log amplitude domain, the measured frequency response H(f) is subtracted from the target frequency response T(f) to obtain the equalizer frequency response G(f). If in the linear amplitude domain then the target frequency response T(f) is divided by the measured frequency response H(f) to obtain the equalizer frequency response G(f).

As well known in the prior art H (f) can be calculated by cross correlating the MLS noise, with the recorded noise to determine the impulse response. A fast Fourier transform (FFT) is applied to obtain the frequency response and from a weighted sum of the FFT bins the measured frequency response H(f) is obtained at a desired set of frequencies. The target frequency response T(f) is predetermined.

Next the error point for a section of the equalizer frequency response G(f), 66, FIG. 3, is determined, then a characteristic frequency (f) and height or gain (g) of the error point of the section is determined, 68. From the frequency (f) and the gain (g) there is generated the filter coefficients (a) and (b) from equations 1 though 5, 70,

$$\begin{matrix}a 1 = K 1 \cdot ( 1 + K 2 ) & ( 1 ) \\ a 2 = K 2 & ( 2 ) \\ b 0 = ( 1 + K 2 + g \cdot ( 1 - K 2 ) ) / 2 & ( 3 ) \\ b 1 = a 1 & ( 4 ) \\ b 2 = ( 1 + K 2 - g \cdot ( 1 - K 2 ) ) / 2 & ( 5 ) \\ K 2 = ( 1 - \frac{γ}{\sqrt{g}} ) / ( 1 + \frac{γ}{\sqrt{g}} ) & ( 6 ) \\ K 1 = - cos ( ω 0 ) & ( 7 ) \\ γ = sinh ( W \cdot ω 0 \cdot log ( 2 ) / ( 2 \cdot sin ( ω 0 ) ) ) \cdot sin ( ω 0 ) & ( 8 ) \\ ω 0 = 2 \cdot π \cdot f 0 / fs & ( 9 )\end{matrix}$$

See The Equivalence of Various Methods of Computing Biquad Coefficients for Audio Parametric Equalizers by Robert Bristow-Johnson, presented at the 97^{th} Convention Nov. 10-13, 1994 San Francisco AES, pages 1-15 herein incorporated in its entirety by this reference.

The determination of an error point is typically made by choosing as the first error point for a first section the point of highest gain. The next error point for the next section would be the next highest gain and so forth. In this particular disclosure there are only four error points or four sections for simplicity of understanding but any number, 8, 10, 16, 32, 50 and so on can be used: it is only a matter of the processing power and how close one seeks to come to the ideal. Note that one of the advantages of this invention is that the computation operations are simpler and can be carried out in digital processors that are already a part of typical sound systems. This is so because this approach while giving excellent results in terms of audio for the listener uses indigenous processors and provides a larger sweet spot or listening area for the user.

Using these equations, f0, W, g, and fs can be converted to biquadratic filter coefficients where f0 is the center frequency of the error point or section, W is the width in octaves, g is the linear gain, and fs is the sampling rate in Hz. Using these equations a set of coefficients a1, a2, b0, b1, and b2 can be calculated for each width. The frequency response for the biquadratic filter is given by the following equation.

$$H ( z ) = \frac{b 0 + b 1 \cdot z + b 2 {z}^{2}}{1 + a 1 z + a 2 {z}^{2}} \qquad ( 10 )$$

Where a1, a2, b0, b1, and b2 are the coefficients and z is equal to e^{jω}, j equals the square root of −1 and ω equals 2ωfₛ, f being the frequency in Hz, fₛ the sampling rate, z a complex number and H(z) also is a complex number. See Oppenheim and Schafer, Discrete-Time Signal Processing, Prentice Hall, Englewood Cliffs, N.J., 1989, herein incorporated in its entirety by this reference.

Using these equations a plurality of parametric frequency responses can be calculated for different widths. Each different width parametric frequency response is compared to the equalizer frequency response at a number of frequencies to determine mismatches, 74. Then the sum of the squares of the mismatch errors is calculated, 76, and the best match is selected, 78. The frequency (f) gain (g) and width (W) of the best match is stored, 80. The equalizer frequency response G (f) is normalized to null the error point of this section. If this is not the last error point section the system returns to step 66 if it is at 84 it moves on to the next step. After the last section error point best match has been determined the filter coefficients are applied to biquad elements to implement the equalizer filter, 86. Once the filter has been implemented in this way the system can operate in the equalizer mode and apply the equalization filter to all the subsequent input signals, 88.

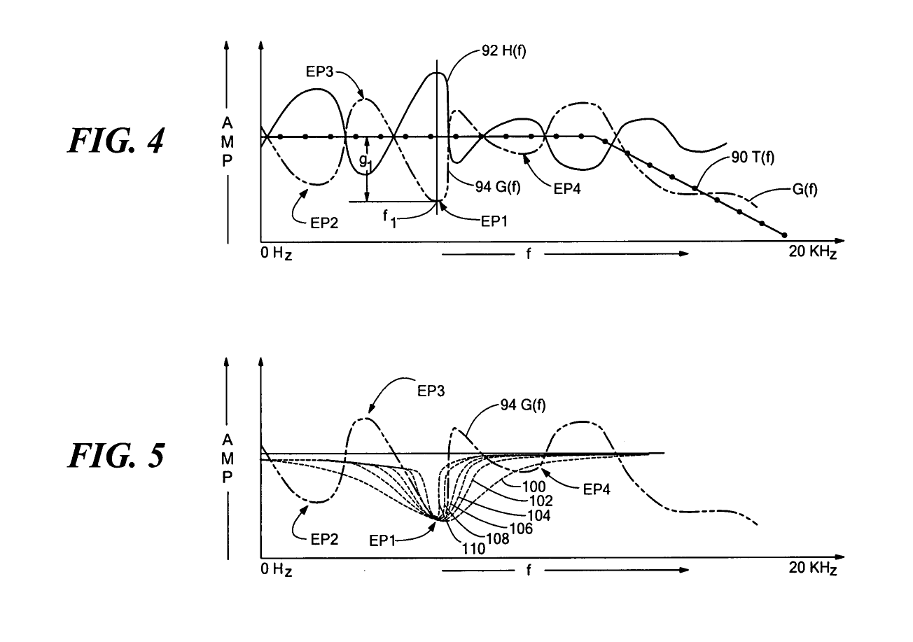

The operation of the invention is shown graphically in FIGS. 4, 5, 6 and 7. In FIG. 4, there is shown the target frequency response 90 T(f), the measured frequency response 92 H(f), and the result of combining those two: the equalizer frequency response 94 G(f). The equalizer frequency response G(f) is obtained here by simply subtracting the measured response 92 H(f) from the target response 90 T(f). In this example, the error points are chosen by selecting the highest absolute gain first, then the next highest absolute gain, then the next and so on. The characteristic gain and frequency used as shown in FIG. 4 is for the first error point EP1, the point that has the highest absolute gain g₁ and the frequency f₁ at that point. In this case four error point sections are chosen EP1, EP2, EP3, and EP4.

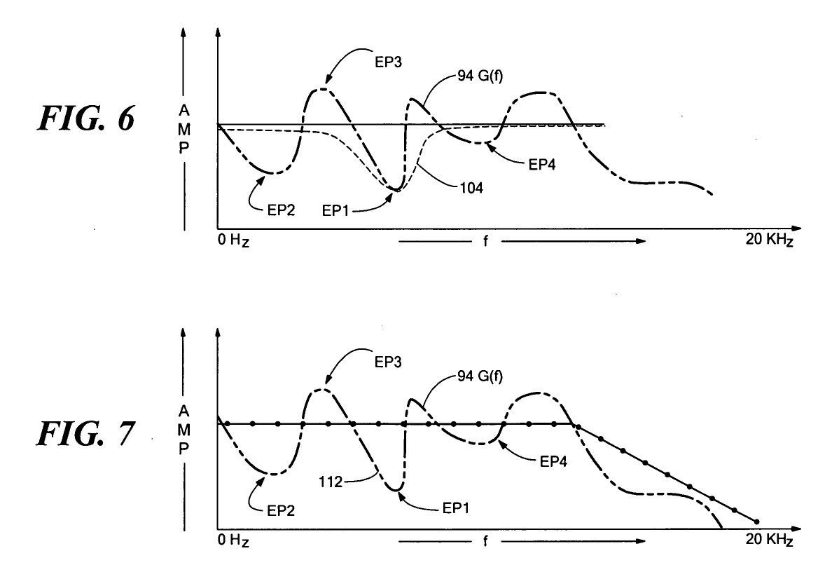

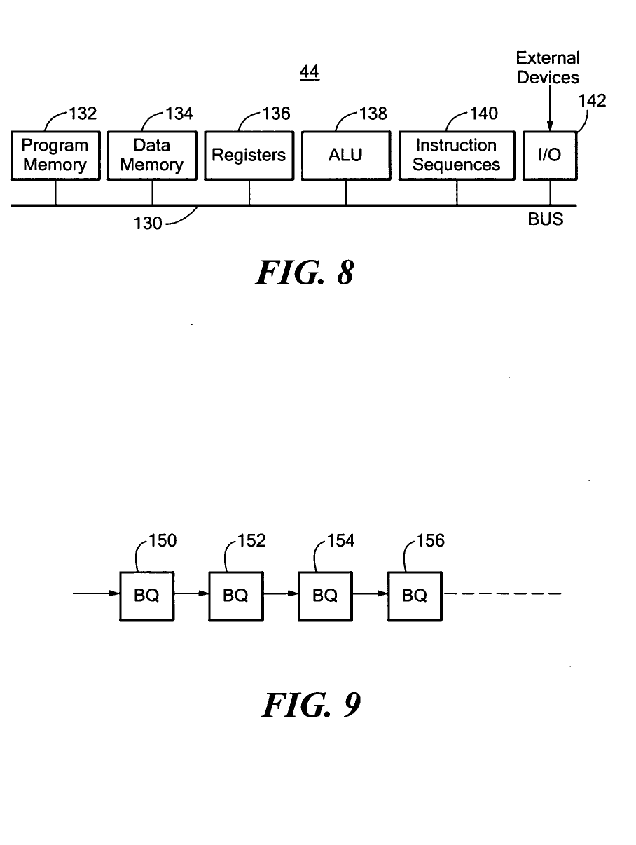

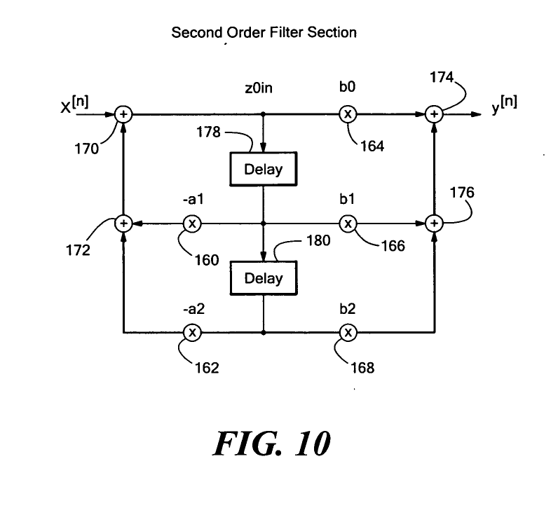

In FIG. 5, a number of parametric frequency responses of different widths (W) in this example, six, 100, 102, 104, 106, 108, 110 are applied and one is found to be the best fit. For example, assuming that response 104 is the best fit, which is shown more clearly in FIG. 6, the frequency gain and width (W) of response 104 will then be stored. It is then used to normalize equalizer frequency response 94 to remove or null error point EP1 shown in phantom at 112 in FIG. 7 and reduce that area ideally to the level of the target frequency response 90 T(f). Thus the best fit match for error point EP1 is now stored and the parametric frequency response of the correct width can be recreated at will, for example, to null EP1 and to later provide, when all four error points have been dealt with, the coefficients to implement the filter. Although these are called error points, it should be understood that they are not a point in the geometric sense as in two points define a line. Rather they are more properly defined as a narrow localized place having a specific indicated position. The digital signal processor 44 of FIG. 2, may typically include a bus 130, FIG. 8, which serves a program memory 132, data memory, 134, registers 136, arithmetic logic unit 138, instruction sequencing circuit 140, and I/O unit 142. It is in the digital processor 44 that the biquad elements 150, 152,154, and 156, FIG. 9, are implemented. There are four biquad elements here because in our example there are but four error point sections. Each biquad includes five multipliers, 160, 162, 164, 166, and 168, FIG. 10, with their respective coefficients −a1, −a2, b0, b1, and b2, respectively. Also included are four summing circuits, 170, 172, 174, and 176 and two sample delay circuits 178 and 180. For each sample input x(n)
y[n]=b0·x[n]+b1·x[n−1]+b2·x[n−2]−a1·y[n−1]−a2·y[n−2] (11)
See Oppenheim and Schafer, Discrete-Time Signal Processing, Prentice Hall, Englewood Cliffs, N.J., 1989, herein incorporated in its entirety by this reference.

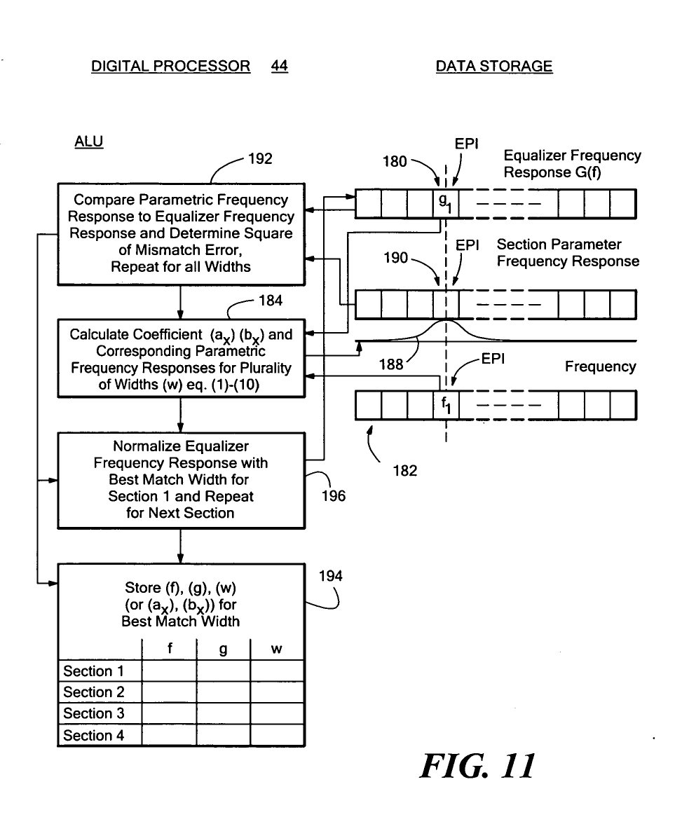

The invention is realizable in apparatus as well as method form. The data structure for carrying out the invention in digital processor 44 is shown in FIG. 11. Digital processor 44 includes among other things the data storage and arithmetic logic unit. The data storage stores in one portion 180 the equalizer frequency response G(f) where it can be seen that the first error point EP 1 is stored as represented by the value g₁ which is the magnitude or gain of that point at a particular frequency f₁ which can be obtained from the second area 182 of data storage. There would typically be 30 frequencies stored at 182 and 30 magnitudes or gain levels stored in storage area 180 as typically the audio spectrum would be arranged in 30⅓ octave steps. Drawing on the value g₁ from storage area 180 and the value f₁ from storage area 182, the ALU at 184 is able to calculate the filter coefficients a1, a2, b0, b1, and b2 and the corresponding parametric frequency responses for a plurality of widths using equations 1-10 as explained previously, one of which is shown graphically at 188 and stored in data storage area 190. The numerical representation of parametric frequency response 190 is compared to that of G(f) in storage area 180 and the square of the mismatch error is determined. This is repeated for all the widths to determine the best match for all the widths in the ALU as indicated at 192. This is done for each of the widths and for each of them the sum of squares of the errors is accumulated. The one with the least error is stored; either the filter coefficients a, b, can be stored or the originating values f, g, W can be stored. In FIG. 11 values f, g, and W are stored for each of the error point sections EP1, EP2, EP3, and EP4 and from those the coefficients can be recalculated. The best match is stored at 196 to normalize the equalizer frequency response by removing the first error point and leaving the second largest or highest gain error point now as the most prominent one for the next series of operations on error point EP2.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A parametric equalizer method comprising:
determining an error point for a section of an equalizer frequency response; and
applying a plurality of different parametric frequency responses to determine the best fit for that error point.

2. The parametric equalizer method of claim 1 in which applying a plurality of different parametric frequency responses includes determining a characteristic frequency and gain of the error point, and generating a plurality of filter coefficients and corresponding parametric frequency responses of different widths.

3. The parametric equalizer method of claim 1 in which applying a plurality of different parametric frequency responses includes comparing each different width parametric frequency response to the equalizer frequency response at a number of frequencies to determine mismatch error.

4. The parametric equalizer method of claim 3 in which applying a plurality of different parametric frequency responses includes calculating the sum of the squares of the mismatch errors and selecting the best match.

5. The parametric equalizer method of claim 1 in which applying a plurality of different parametric frequency responses includes storing the characteristic frequency and gain of the error point and best match width parametric frequency response.

6. The parametric equalizer method of claim 5 further including normalizing the equalizer frequency response using the best match parametric frequency response width to null said error point of said section.

7. The parametric equalizer method of claim 6 further including determining second error point for a second section and applying a plurality of different parametric frequency responses to determine the best fit for that second error point.

8. The parametric equalizer method of claim 7 further including after the best fit has been determined for the last error point section applying each of the filter coefficients from each error point section to a filter element to implement an equalizer filter.

9. The parametric equalizer method of claim 8 further including applying said equalizer filter to input signals.

10. The parametric equalizer method of claim 8 in which said filter elements are embodied in a digital processor.

11. The parametric equalizer method of claim 2 in which said characteristic frequency and gain are the frequency at the peak gain.

12. The parametric equalizer method of claim 1 in which said equalizer frequency response is determined by a target frequency response normalized by a measured frequency response.

13. A parametric equalizer comprising a digital processor configured to:
determine an error point for a section of an equalizer frequency response; and
apply a plurality of different parametric frequency responses to determine the best fit for that error point.

14. The parametric equalizer of claim 13 in which said digital processor in applying a plurality of different parametric frequency responses is further configured to determine a characteristic frequency and gain of the error point, and generate a plurality of filter coefficients and corresponding parametric frequency responses of different widths.

15. The parametric equalizer of claim 13 in which said digital processor applying a plurality of different parametric frequency responses is further configured to compare each different width parametric frequency response to the equalizer frequency response at a number of frequencies to determine mismatch error.

16. The parametric equalizer of claim 15 in which said digital processor in applying a plurality of different parametric frequency responses is further configured to calculate the sum of the squares of the mismatch errors and select the best match.

17. The parametric equalizer of claim 16 in which said digital processor in applying a plurality of different parametric frequency responses is further configured to store the characteristic frequency and gain of the error point, and generate a plurality of filter coefficients and corresponding parametric frequency responses of different widths.

18. The parametric equalizer of claim 17 in which said digital processor is further configured to normalize the equalizer frequency response using the best match parametric frequency response width to null said error point of said section.

19. The parametric equalizer of claim 18 in which said digital processor is further configured to determine a second error point for a second section and apply a plurality of different parametric frequency responses to determine the best fit for that second error point.

20. The parametric equalizer of claim 19 in which said digital processor is further configured to, after the best fit has been determined for the last error point section, apply each of the filter coefficients from each error point section to a filter element to implement an equalizer filter.

21. The parametric equalizer of claim 20 in which said digital processor is further configured to apply said equalizer filter to input signals.

22. The parametric equalizer of claim 20 in which said filter elements are embodied in the digital processor.

23. The parametric equalizer of claim 14 in which said characteristic frequency and gain are the frequency at the peak gain.

24. The parametric equalizer of claim 13 in which said equalizer frequency response is determined by a target frequency response normalized by a measured frequency response.

25. A method of equalizing a sound system comprising:
determining an error point for a section of an equalizer frequency response; and
applying a plurality of different parametric frequency responses to determine the best fit for that error point.

26. The method of equalizing a sound system of claim 25 in which applying a plurality of different parametric frequency responses includes determining a characteristic frequency and gain of the error point, and generating a plurality of filter coefficients and corresponding parametric frequency responses of different widths.

27. The method of equalizing a sound system of claim 25 in which applying a plurality of different parametric frequency responses includes comparing each different width parametric frequency response to the equalizer frequency response at a number of frequencies to determine mismatch error.

28. The method of equalizing a sound system of claim 27 in which applying a plurality of different parametric frequency responses includes calculating the sum of the squares of the mismatch errors and selecting the best match.

29. The method of equalizing a sound system of claim 26 in which applying a plurality of different parametric frequency responses includes storing the characteristic frequency and gain of the error point and best match width parametric frequency response.

30. The method of equalizing a sound system of claim 29 further including normalizing the equalizer frequency response using the best match parametric frequency response width to null said error point of said section.

31. The method of equalizing a sound system of claim 30 further including determining second error point for a second section and applying a plurality of different parametric frequency responses to determine the best fit for that second error point.

32. The method of equalizing a sound system of claim 31 further including after the best fit has been determined for the last error point section applying each of the filter coefficients from each error point section to a filter element to implement an equalizer filter.

33. The method of equalizing a sound system of claim 32 further including applying said equalizer filter to input signals.

34. The method of equalizing a sound system of claim 32 in which said filter elements are embodied in a digital processor.

35. The method of equalizing a sound system of claim 26 in which said characteristic frequency and gain are the frequency at the peak gain.

36. The method of equalizing a sound system of claim 25 in which said equalizer frequency response is determined by a target frequency response normalized by a measured frequency response.

37. A parametric equalizer for a sound system comprising a digital processor configured to:
determine an error point for a section of an equalizer frequency response; and
apply a plurality of different parametric frequency responses to determine the best fit for that error point.

38. The parametric equalizer for a sound system of claim 37 in which said digital processor applying a plurality of different parametric frequency responses is further configured to determine a characteristic frequency and gain of the error point, and generate a plurality of filter coefficients and corresponding parametric frequency responses of different widths.

39. The parametric equalizer for a sound system of claim 37 in which said digital processor applying a plurality of different parametric frequency responses is further configured to compare each different width parametric frequency response to the equalizer frequency response at a number of frequencies to determine mismatch error.

40. The parametric equalizer for a sound system of claim 39 in which said digital processor applying a plurality of different parametric frequency responses is further configured to calculate the sum of the squares of the mismatch errors and select the best match.

41. The parametric equalizer for a sound system of claim 40 in which said digital processor applying a plurality of different parametric frequency responses is further configured to store the characteristic frequency and gain of the error point and best match width parametric frequency response.

42. The parametric equalizer for a sound system of claim 41 in which said digital processor is further configured to normalize the equalizer frequency response using the best match parametric frequency response width to null said error point of said section.

43. The parametric equalizer for a sound system of claim 42 in which said digital processor is further configured to determine a second error point for a second section and apply a plurality of different parametric frequency responses to determine the best fit for that second error point.

44. The parametric equalizer for a sound system of claim 43 in which said digital processor is further configured to, after the best fit has been determined for the last error point section, apply each of the filter coefficients from each error point section to a filter element to implement an equalizer filter.

45. The parametric equalizer for a sound system of claim 44 in which said digital processor is further configured to apply said equalizer filter to input signals.

46. The parametric equalizer for a sound system of claim 44 in which said filter elements are embodied in the digital processor.

47. The parametric equalizer for a sound system of claim 38 in which said characteristic frequency and gain are the frequency at the peak gain.

48. The parametric equalizer for a sound system of claim 37 in which said equalizer frequency response is determined by a target frequency response normalized by a measured frequency response.
